(19) United States
(12) Patent Application Publication
(10) Pub. No.: US 2025/0365890 A1
(43) Pub. Date: Nov. 27, 2025

(54) Electrical Assembly Configured to Install Electronic Devices and a Liquid-Cooled Electronic System

(71) Applicant: Tyco Electronics (Shanghai) Co., Ltd., Shanghai (CN)

(72) Inventors: Hua (Andy) Li, Shanghai (CN); Fengping (Alex) Xu, Shanghai (CN); Wei Yao, Kunshan (CN); Mingqiong Gu, Shanghai (CN)

(73) Assignee: Tyco Electronics (Shanghai) Co., Ltd., Shanghai (CN)

(21) Appl. No.: 19/219,201

(22) Filed: May 27, 2025

(30) Foreign Application Priority Data
May 27, 2024 (CN) 202410668869.7

(51) Int. Cl. H05K 7/20; H05K 5/06

(52) U.S. Cl. CPC H05K 7/20236; H05K 5/069; H05K 7/20263; H05K 7/20272; H05K 7/20409; H05K 7/203; H05K 7/20327

(57) ABSTRACT

An electronic assembly for installing electronic devices includes a housing, an intermediate plate, an inlet pipe, an outlet pipe, and a plurality of lead-wires. The housing has a wall portion which circumscribes and defines a hollowed chamber. The intermediate plate is provided within the chamber and is fixed to the wall portion, with the electronic devices being fixed to and electrically coupled with the intermediate plate. The inlet pipe and the outlet pipe are respectively formed to penetrate the wall portion and configured to introduce a coolant into the chamber and discharge the coolant from the chamber. At least one of the electronic devices and the intermediate plate is electrically coupled to an exterior of the housing through the plurality of lead-wires. Each electronic device is in a sealed package form and immersed in the coolant.

### CROSS-REFERENCE TO RELATED APPLICATION

This application claims the benefit of Chinese Patent Application No. 202410668869.7 filed on May 27, 2024, in the State Intellectual Property Office of China, the whole disclosure of which is incorporated herein by reference.

### FIELD OF THE DISCLOSURE

This disclosure relates to an electrical assembly configured to install electronic devices and a liquid-cooled electronic system, and more specifically, to an electronic assembly for installing electronic devices, for example in a field of electronic technology, which is configured to cool the electronic devices in a sealed package form; and to a liquid-cooled electronic system comprising the electronic assembly and the electronic devices.

### BACKGROUND OF THE INVENTION

High-performance computing applications such as artificial intelligence, machine learning, and data mining and the like, can benefit from high computational densities. For example, by placing computing chips close to each other or one another, the amount of physical space taken up to achieve a particular computational capacity can be reduced, and communication bandwidth and latency between chips can be improved, and so on. Packaging technologies such as system-on-chip (SOC) have made it feasible to build very high-density computing systems with virtually no area provided between dies. And as the performance of electronic systems increases and the sizes of electronic components shrink, significant heat may be generated in ever-smaller volumes. As a result, packaged electronic circuits or chips can provide significant improvements in computational density, but there are also significant challenges. When a plurality of packaged electronic circuits or chips are arranged in very close proximity to one another, there may be significant power consumption in a relatively small area, which may present significant challenges to the cooling effects of the packaged electronic circuits or chips and other components in the vicinity.

However, conventional cooling designs for computing systems, comprise cold plate cooling solutions utilizing thermally conductive cold plates (typically, the cold plate(s) may be additionally provided, for example, with heat dissipators (e.g., finned heat sinks, or additional heat spreader(s)) pressed against an outer surface of the cold plate, or optionally with built-in microchannels for coolant), or immersion cooling solutions in which the entire chassis of the computing system is immerged in a non-conductive coolant. Each of these conventional cooling designs can face significant cooling challenges once faced with HPC application scenarios and can be inefficient in their use of space, which can result in reduced cooling performance, increased physical space requirements, etc., and are not suited to address the cooling of chips or packaged electronic circuits in HPC application scenarios.

In cooling designs of the prior art, the cooling efficiency of cold plate cooling solutions may be lower than that of immersion cooling, but immersion cooling solutions is implemented by typically placing the entire chassis of the computing system into the coolant, or through additional coolant piping between components within the computing system, which requires the design of coolant layout pathways and respective seals for the overall chassis and for the components, thus often requiring a compromise/tradeoff between the circuit design of the components and the cooling design, and the coolant often needs to be non-conductive.

In order to avoid and minimize such problems, it is generally possible to improve manufacturing distortion by strictly monitoring the manufacturing process, as well as to control thermal distortion during the welding process by, for example, enhancing heat dissipation and controlling the duration of a single weld as well as the time interval between welds, thereby contributing to the reduction of the distortion and the improvement of the resulting empty weld problem. However, the use of such in-process control of manufacturing results in increased manufacturing costs and still does not prevent the generation of defective products.

In view of the above technical problems, there is an urgent need in this field to design a cooling solution with simple structure at a controllable cost, which is capable of realizing a significant improvement in cooling efficiency relative to a cold plate so as to effectively address the cooling issue of packaged electronic devices, and does not require additional changes to the circuit design and additional laying of coolant flow paths, which are otherwise required in the case of the overall immerged cooling solution.

### SUMMARY OF THE INVENTION

According to an embodiment of the present disclosure, an electronic assembly for installing electronic devices includes a housing, an intermediate plate, an inlet pipe, an outlet pipe, and a plurality of lead-wires. The housing has a wall portion which circumscribes and defines a hollowed chamber. The intermediate plate is provided within the chamber and is fixed to the wall portion, with the electronic devices being fixed to and electrically coupled with the intermediate plate. The inlet pipe and the outlet pipe are respectively formed to penetrate the wall portion and configured to introduce a coolant into the chamber and discharge the coolant from the chamber. At least one of the electronic devices and the intermediate plate is electrically coupled to an exterior of the housing through the plurality of lead-wires. Each electronic device is in a sealed package form and immersed in the coolant.

### DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 illustrates, in stereoscopic view, a schematic three-dimensional view of an electronic assembly configured to install electronic devices, and a liquid-cooled electronic system comprising the electronic assembly and the electronic devices;

FIG. 2 schematically illustrates, in a partially explored way based on functionality of the components/assembly, an exploded view of the electrical assembly and the liquid-cooled electronic system as illustrated in FIG. 1 according to the embodiment;

FIG. 3(a) illustrates a front view of FIG. 1 according to an embodiment;

FIG. 3(b) illustrates a left view of FIG. 1 according to the embodiment;

FIG. 3(c) illustrates a top view of FIG. 1 according to the embodiment;

FIG. 3(d) illustrates a bottom view of FIG. 1 according to the embodiment.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

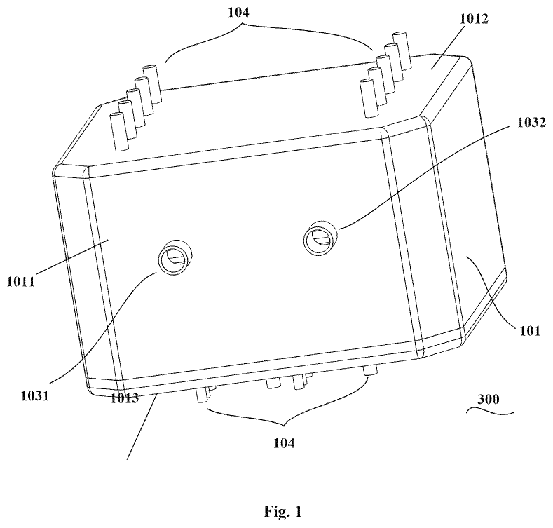

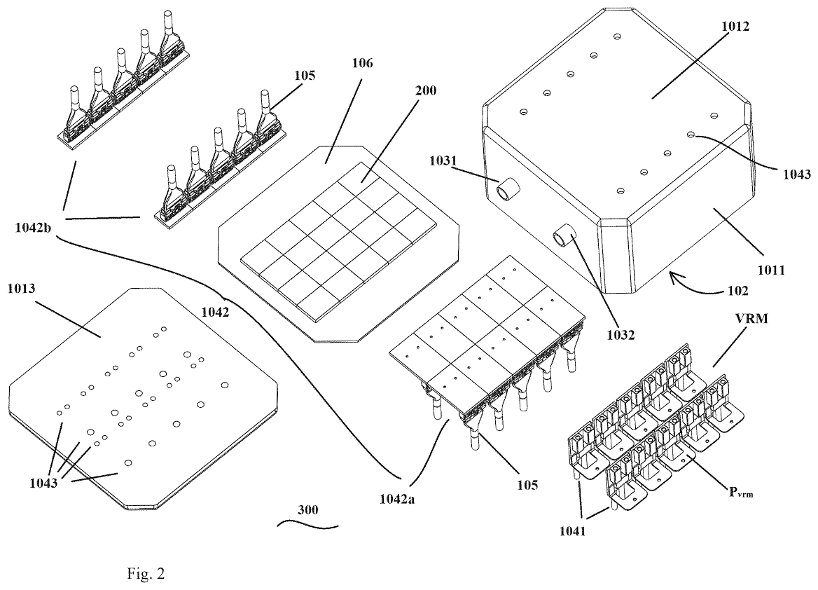

FIG. 1 illustrates, in stereoscopic view, a schematic three-dimensional view of an electronic assembly configured to install electronic devices, and a liquid-cooled electronic system comprising the electronic assembly and the electronic devices. FIG. 2 schematically illustrates, in a partially explored way based on functionality of the components/assembly, an exploded view of the electrical assembly and the liquid-cooled electronic system as illustrated in FIG. 1 according to the embodiment.

According to an overall technical concept as disclosed herein, for example, as illustrated in FIG. 1 and FIG. 2, an electronic assembly 100 configured to install electronic devices 200 is provided, the electronic assembly 100 comprising: a housing 101, comprising a wall portion which circumscribes and defines a hollowed chamber 102; an intermediate plate 106, which is provided within the chamber 102 and fixed to the wall portion, with the electronic devices 200 being fixed to and electrically coupled with the intermediate plate 106; an inlet pipe 1031 and an outlet pipe 1032 (as labeled, and alternatively, the inlet pipe and the outlet pipe may be interchangeable) which are respectively formed to penetrate the wall portion and configured to introduce a coolant into the chamber 102 and discharge the coolant from the chamber 102; and a plurality of lead-wires 104, through which at least one of the electronic devices 200 and the intermediate plate 106 is electrically coupled to an exterior of the housing 101, with each electronic device 200 being in a sealed package form and immersed in the coolant. By way of example, the electronic devices 200 may be computing chips, ASIC circuits, and the like.

By way of example, herein, the intermediate plate 106 acts as a cold plate, which may be a structure having thermal conductivity and heat dissipation functions by being made of a material with good thermal conductivity and is configured to be cooled by the flow of coolant passing thereover for efficient transfer and dissipation of heat from the object to be thermally conducted or dissipated.

Based on the electronic assembly 100 configured to install electronic devices 200 of the above-described settings, electronic devices 200 which are encapsulated hermetically, i.e., in a sealed package form, are above all installed onto the intermediate plate 106 functioning as a cold plate; and then, the electronic devices 200 and the intermediate plate 106 are placed together into the reservoir housing which is enclosed, and are subsequently fluidly communicating with the exterior of the housing via both the inlet pipe 1031 and the outlet pipe 1032, such that the coolant is continuously introduced into the chamber 102 as defined in the housing for accommodating the electronic devices 200 and the cold plate to immerse and in turn cool the electronic devices 200, and then the coolant which absorbs heat from electronic devices 200 and the like is continuously discharged. As such, the cooling efficiency for the electronic devices 200 may be enhanced, thereby ensuring that a higher cooling efficiency than that of the conventional cooling solution merely with cold plate is achieved, also effectively avoiding design modifications such as use of the conventional overall immersion cooling solution; and as to the choice of specific coolant, merely the cooling efficiency is taken into consideration, regardless of properties like whether it is electrically conductive. Moreover, complexity in system structure and assembly operation can be reduced, such that an improved cooling quality for the packaged electronic device 200 can be realized at a controlled cost with simple structure and assembly operation.

In specific embodiments, for example, the wall portion comprises a peripheral wall 1011, and both a top wall 1012 and a bottom wall 1013 disposed opposite to each other and abutting against the peripheral wall 1011 respectively, with at least one of the top wall 1012 and the bottom wall 1013 being removably joined to the peripheral wall 1011, so as to facilitate placement of the intermediate plate 106 and the electronic devices 200 into the interior of the chamber 102 and removal of the intermediate plate 106 and the electronic devices 200 out of the interior of the chamber; and with the peripheral wall 1011, the top wall 1012 and the bottom wall 1013 jointly defining the housing which is enclosed such that the chamber 102 is in turn surrounded and enclosed therein. In an exemplary embodiment, as illustrated, merely the bottom wall 1013 is removably joined to the peripheral wall 1011. Alternatively, or additionally, the top wall 1012 is removably joined to the peripheral wall 1011. With such settings, it facilitates both placement and removal of the intermediate plate 106 and the electronics 200.

In further specific embodiments, for example, the chamber 102 is in fluid communication with the exterior of the housing 101 merely via the inlet pipe 1031 and the outlet pipe 1032, with an electrical connection between the chamber 102 and the exterior of the housing 101 comprising merely an electrical connection between the electronic devices 200 and the exterior of the housing 101 via the plurality of lead-wires 104.

As such, the housing of such electronic assembly 100 defines the chamber 102 which is enclosed therein, and its physical connection/contact with the exterior/outside of the housing (i.e. ambient environment) consists of only two types, i.e. on the one hand, a fluid communication (for transferring the coolant medium) between the exterior/outside of the housing and the chamber 102, as realized merely via the inlet pipe 1031 and the outlet pipe 1032; and on the other hand, an electrically conductive hardware connection as realized via the plurality of lead-wires 104 between the exterior/outside of the housing and both the intermediate plate 106 and the electronic devices 200 accommodated in the chamber 102. Thereby, the chamber 102 is implemented as a confined/enclosed space, and can realize cooling of the electronic devices 200 functioning as the heat source and respective functional supporting components such as intermediate plate 106 (which is typically electrically conductive, such as a silicon interlayer, a PCB, etc.), the voltage regulator modules (i.e. VRM, i.e., Voltage Regulator Module, as illustrated) and the like, within the chamber 102, by a circulating coolant which is pumped into the chamber via the inlet pipe 1031 and discharged out of the chamber via the outlet pipe 1032.

Considering that, for example as illustrated, these electronic devices 200 and functional support components are in hermetically sealed packages, i.e., in a sealed package form, it is thus possible to efficiently cool these devices by delivering the coolant directly into the chamber 102, on the one hand, essentially realizing localized immersion cooling of a plurality of integrated modules, in other words, once a specific number of electronic assembly 100 units are present in an overall machine, each electronic assembly 100 unit comprises electronic devices 200 functioning as the heat source and respective functional supporting components therefor, located within the chamber 102 of the housing, then, each electronic assembly 100 unit may be considered as an integrated module acting as a localized heat source at a specific location of the overall machine. In other words, such a number of units which are cooled by local immersion cooling can be provided merely at different locations of the machine for localized immersion cooling, instead of placing the whole machine into an immersion coolant environment due to the cooling demand as in the conventional overall immersion cooling solution, and there is no need for any re-design of the layout of the circuits, thus simplifying both structure and assembly operations. On the other hand, as the coolant flows through the intermediate plate 106 (which acts as a cold plate) within the chamber 102 (and the electronic device 200 provided thereon), the cooling efficiency is apparently superior to that of the conventional cooling solution with cold plate.

As illustrated in FIG. 1 and FIG. 2, by way of example, the inlet pipe 1031 and the outlet pipe 1032 are distributed to extend through the peripheral wall 1011, and the plurality of lead-wires 104 extend through a perforated surface of at least one of the top wall 1012 and the bottom wall 1013. As such, it facilitates both fluidic coupling and electrical connection between the interior of the housing and the exterior of the housing, respectively.

Accordingly, as an example, the electronic assembly 100 further comprises a gasket 105, which is provided between the plurality of lead-wires 104 and the wall portion, and is configured to form a waterproof seal between the plurality of lead-wires 104 and the wall portion. With such settings, it facilitates ensuring that the chamber 102 is airtight except for respective inner cavities of the inlet pipe 1031 and the outlet pipe 1032 which are used to function as channels for coolant flow, in order to avoid leakage of coolant from the rest of the housing by osmosis.

In exemplary embodiments, for example, the gasket 105 is sleeved on outer peripheries of respective lead-wires of the plurality of lead-wires 104, and is pressed against the perforated surface of a respective one of the top wall 1012 and the bottom wall 1013 through which the plurality of lead-wires 104 extend, to seal around holes 1043 formed in the perforated surface for passing the plurality of lead-wires 104 therethrough. Dimensions of these holes correspond to specific types of lead-wires penetrated herein, and thus may be the same or different, for example the same as shown.

By way of example, the gasket 105 is a sealing liner made of a non-conductive material. In more specific embodiments, for example, the non-conductive material comprises rubber.

It is to be noted that, in order to ensure sealing of the inlet pipe 1031 and the outlet pipe 1032 with respect to the wall portion, then there exist specifically two exemplary cases.

In an exemplary embodiment, by way of example, the inlet pipe 1031 and the outlet pipe 1032, as well as the peripheral wall 1011 are integrally formed. In such a condition, upon consideration that this design as integrally formed, whereby the inlet pipe 1031 and the outlet pipe 1032 are already integral with the wall portion, thus no additional sealing may be required to be provided therebetween.

As another embodiment, for example, alternatively, the inlet pipe 1031 and the outlet pipe 1032 are inserted in respective holes for the pipes formed through the peripheral wall 1011; and the electronic assembly 100 further comprises a sealing ring, which is additionally provided and sleeved on outer peripheries of the inlet pipe 1031 and the outlet pipe 1032 and seals between inner surfaces of the respective holes for the pipes on the peripheral wall 1011 and both the inlet pipe 1031 and the outlet pipe 1032, by pressuring against thereon. As such, the sealing of both inlet pipe 1031 and outlet pipe 1032 relative to the wall portion (specifically, the peripheral wall 1011) is thereby achieved. It facilitates ensuring that the chamber 102 is airtight except for the respective inner cavities of the inlet pipe 1031 and the outlet pipe 1032 for functioning as channels for coolant flow, so as to avoid leakage of coolant from the rest of the housing by osmosis.

In exemplary embodiments, for example, the intermediate plate 106 is a silicon substrate or a PCB.

Moreover, in exemplary embodiments, by way of example, the coolant is water or a conductive coolant, such as water or another refrigeration agent (e.g., Freon R22). Just because the fact as previously mentioned, the electronic assembly 100 of the present disclosure substantially implements localized immersion cooling for a plurality of integrated modules, and thus, also upon consideration that the electronic devices 200 and respective supporting components therefor (such as the intermediate plate 106, VRMs, etc.) are in a sealed package form, in application scenarios of the present disclosure, for example as illustrated, then, there is no need for a conventional overall immersion cooling solution, wherein only non-conductive coolant can be selected due to immersion of the entire machine. Therefore, a primary factor in the selection of coolant is cooling efficiency, regardless of other physical properties such as whether it is electrically conductive or whether it is chemically reactive with the electronic devices 200 and its functional support components (such as the intermediate plates 106, VRMs, etc.). This facilitates optimizing the selection of the coolant.

Optionally, as an example, each of the plurality of lead-wires 104 is one of a pin, an electrical connection terminal, or a wire. In other words, the plurality of lead-wires 104 may be rigid pins, as shown; alternatively, the plurality of leads 104 may be, for example, rigid wiring terminals, or flexible wires.

In specific embodiments, for example as illustrated, the plurality of lead-wires 104 comprise: a plurality of power supply lead-wires 1041 electrically coupled to the intermediate plate 106 and configured to supply power to at least one of the electronic devices 200 and the intermediate plate 106; and a plurality of signal lead-wires 1042, the plurality of signal lead-wires 1042 comprising: a plurality of input signal lead-wires 1042a configured to input data to at least one of the electronic devices 200 and the intermediate plate 106, and a plurality of output signal lead-wires 1042b configured to output data from at least one of the electronic devices 200 and the intermediate plate 106.

And, in further exemplary embodiments, typically, for example typically as illustrated in FIG. 1 and FIG. 2, the electronic devices 200 comprise a plurality of electronic circuit units, which are mounted to an upper surface of the intermediate plate 106 facing towards the top wall 1012, in a sealed package form; and the electronic assembly 100 further comprises a plurality of voltage regulator modules VRM mounted on a lower surface of the intermediate plate 106 opposite to the upper surface, with each voltage regulator module being arranged to be electrically connected to a power source outside of the housing 101 via a respective power supply lead-wire of the plurality of power supply lead-wires 1041 and to a respective electronic circuit unit of the plurality of electronic circuit units via the intermediate plate 106. As such, a complete circuit connection inside the chamber 102 of the electronic assembly 100 is thus realized.

More specifically, for example as illustrated, each of the plurality of voltage regulator modules VRMs may be securely coupled (e.g. by means of a threaded connection) to the bottom wall by means of its adapter plate Pᵥᵣₘ, and is substantially coupled integrally with the bottom wall; when subsequently assembling the electronic assembly, a pin slot (i.e., slot for receiving respective pin) of each voltage regulator module VRM may be aligned with the respective pin at a base of the respective input signal lead-wire and are thus in an insertion fit to form a power supply connection for the respective electronic device. The voltage regulator module VRMs and the respective input signal lead-wires are thus accurately and properly positioned and secured.

Moreover, for example as illustrated, the plurality of input signal lead-wires 1042a are arranged to extend from the lower surface of the intermediate plate 106 through the bottom wall 1013 and electrically connected to the electronic devices 200 via the intermediate plate 106, and the plurality of output signal lead-wires 1042b are arranged to extend from the upper surface of the intermediate plate 106 through the top wall 1012 and are electrically connected from the electronic devices 200 to the exterior of the housing 101 via the intermediate plate 106. Such signal routings are set such that main flow direction of the input and output of the coolant is orthogonal to signal paths; and upon consideration that in a “in-position” state of the electronic assembly after installation, the coolant is typically horizontally fed into the housing and outputted from the housing, then the direction of the setting of such lead-wires may typically be in a vertical direction from the bottom to the top, i.e., the lead-wires are typically oriented vertically from the bottom to the top, whereby these settings facilitate the exclusion of interference with the signals of the electronic circuits.

Upon consideration of further enhancement of the heat transfer effect from the inside of the housing of the electronic assembly 100, in particular from the electronic devices 200 provided as a heat source, and respective functional support components therefor, in the chamber 102, then, in an additional exemplary embodiment, for example, the electronic assembly 100 further comprises a heat dissipator provided in close proximity to respective package surfaces of the electronic devices 200 or to the intermediate plate 106.

In further exemplary embodiments, for example, the heat dissipator is made of metal or alloy material, typically such as, copper, aluminum and alloy materials thereof possessing high thermal conductivity.

In exemplary embodiments, as to specific form of such heat dissipator as additionally provided, the heat dissipator comprises a plurality of heat dissipating fins, which are provided on a common thermally conductive floor, which may in turn be tightly adhered to locations where the heat dissipation is to be enhanced, on the surface of the intermediate plate 106, in order to facilitate an enhanced heat transfer therefrom.

Upon further consideration of obtaining a further improved cooling effect of the coolant by means of flow path optimization, as an additional example, the electronic assembly 100 further comprises a plurality of flow guides, which extend from the wall portion towards the intermediate plate 106, for example setting manually empirically, or simulating with software, the different heat dissipation effects in case of different coolant distributions, so as to be selectively mounted (by snap-fit or other alternative mating ways) at different positions on the respective inner surfaces of the top wall 1012, the bottom wall 1013, or the peripheral wall 1011 (e.g. at recesses on the inner surfaces as preset for selective installation of these flow guides) and pointing inwardly towards the chamber 102, and the plurality of flow guides are cooperatively arranged to constrain dimensions of a flow path of the coolant flowing towards the electronic devices 200. As a result, based on the Bernoulli principle, an increased flow rate towards the electronic devices 200 disposed as a heat source and respective functional support parts therefor, within the chamber 102 of the housing, can be realized, facilitating the realization of an enhanced local heat transfer effect utilizing the coolant. Based on the electronic assembly 100 of above-described settings, it is then capable of

immerging an integrated module of a high-heat generation computing system comprising encapsulated/packaged high-performance computing units, including AI computing units, in a cooling liquid; and the computing units and respective supporting components therefor, such as a PCB, a silicon interlayer or intermediate plate, a voltage regulator modules (i.e., a VRMs), and the like, are assembled together as a liquid-cooled plate storage tank to act as an integral assembly; and thereafter, the immersion liquid can flow in and out of the housing by penetrating pipes provided in the walls of the liquid cold plate storage tank, thereby realizing cooling of the encapsulated/packaged computing units on the cold plate as provided in the storage tank, by liquid cooling. The power supply terminals and signal terminals of the computing units can be connected to other external components by means of terminal cables or pins for power supply and signal transmission, respectively. Seals (such as rubber gaskets, and the like) are provided between the terminals and the cold plate tank for sealing, which prevents the coolant from leaking out of the tank. Inside the cold plate tank, the computing units and respective components therefor can be assembled together with internal features of the tank. As a result, this immersion cooling of integrated modules for encapsulated computing units and their supporting components may be superior to conventional cold plate cooling solution (since cold plate cooling is for example usually carried out with the aid of a cold flow of a cooling medium passing through the surface of the cold plate). This also simplifies the design of the cooling structure.

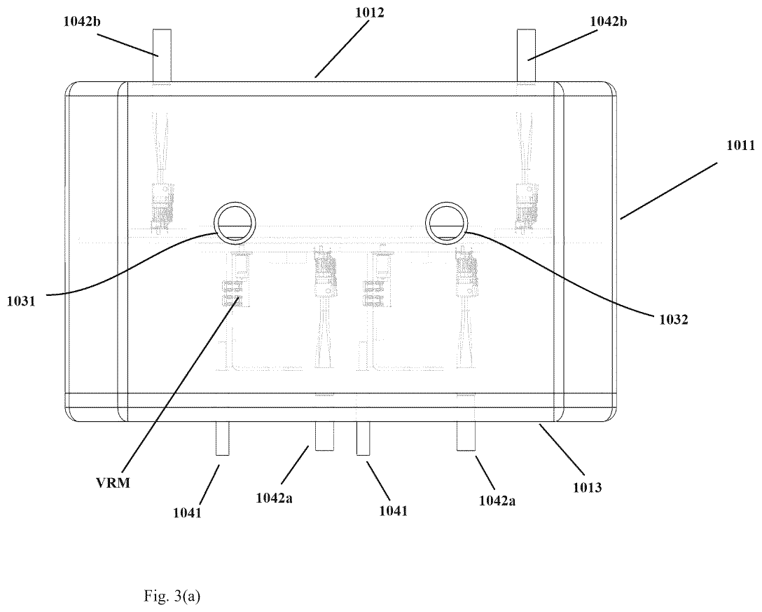

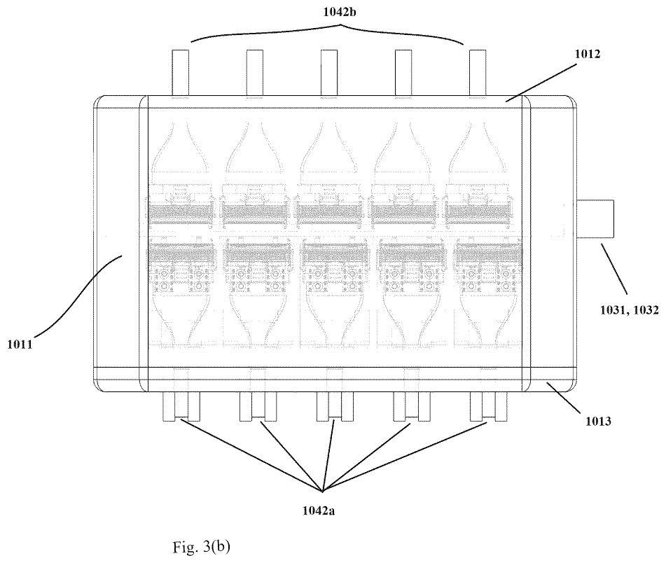

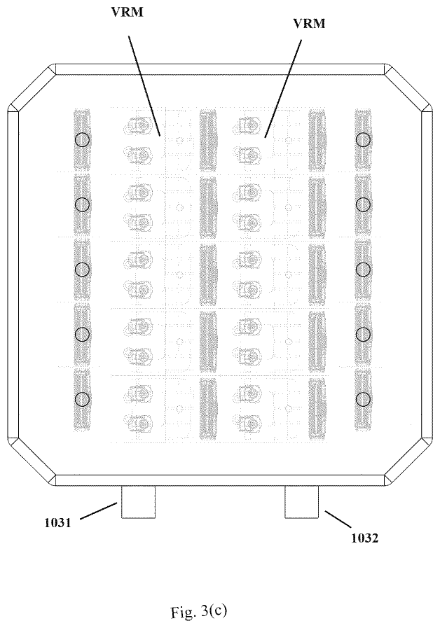

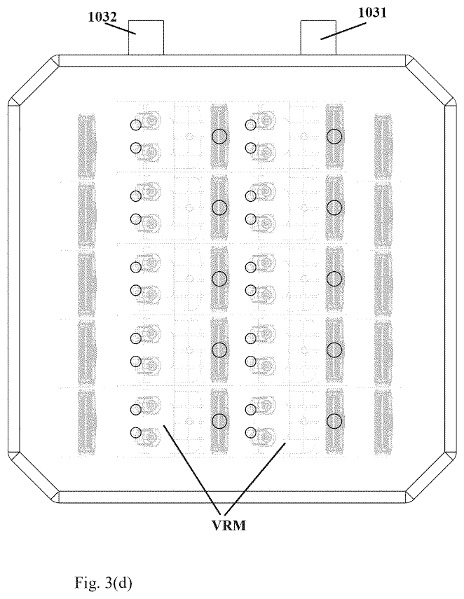

FIG. 3(a) illustrates a front view of FIG. 1 according to an embodiment; FIG. 3(b) illustrates a left view of FIG. 1 according to the embodiment; FIG. 3(c) illustrates a top view of FIG. 1 according to the embodiment; FIG. 3(d) illustrates a bottom view of FIG. 1 according to the embodiment.

According to another aspect of the present disclosure, as illustrated in FIG. 1 and FIG. 2, and also in view of FIG. 3(a) to FIG. 3(d), a liquid-cooled electronic system 300 is provided in the present disclosure, comprising: the electronic assembly 100 as above; and the electronic devices 200.

Moreover, upon consideration that the liquid-cooled electronic system 300 as provided in another aspect of the present disclosure comprises the aforementioned electronic assembly 100 and the electronic devices 200, then, the liquid-cooled electronic system 300 also has the advantages of the aforementioned electronic assembly 100, which fact will not be set forth here repeatedly

As compared with solutions of relevant art such as cold plate cooling solution and overall immersion solution, the electronic assembly configured to install electronic devices 200, and the liquid-cooled electronic system 300, as provided in embodiments of the present disclosure, have at least following superior technical effects:

As to the electronic assembly 100 configured to install electronic devices 200 and the liquid-cooled electronic system 300 according to various embodiments of the present disclosure described above, they are capable of implementing that:

electronic devices 200 which are encapsulated hermetically, i.e., in a sealed package form, are above all installed onto the intermediate plate 106 functioning as a cold plate; and then, the electronic devices 200 and the intermediate plate 106 are placed together into the reservoir housing which is enclosed, and are subsequently fluidly communicating with the exterior of the housing via both the inlet pipe 1031 and the outlet pipe 1032, such that the coolant is continuously introduced into the chamber 102 as defined in the housing for accommodating the electronic devices 200 and the cold plate to immerse and in turn cool the electronic devices 200, and then the coolant which absorbs heat from electronic devices 200 and the like is continuously discharged.

As such, the cooling efficiency for the electronic devices 200 may be enhanced, thereby ensuring that a higher cooling efficiency than that of the conventional cooling solution merely with cold plate is achieved, also effectively avoiding design modifications such as use of the conventional overall immersion cooling solution; and as to the choice of specific coolant, merely the cooling efficiency is taken into consideration, regardless of properties like whether it is electrically conductive. Moreover, complexity in system structure and assembly operation can be reduced, such that an improved cooling quality for the packaged electronic device 200 can be realized at a controlled cost with simple structure and assembly operation.

It may be understood by those skilled in the art that the embodiments described above are exemplary and may be improved by those skilled in the art, and the structures described in various embodiments can be freely combined without conflicts in structure or principle.

Although the disclosure is described in view of the attached drawings, the embodiments illustrated in the attached drawings are intended to illustrate preferred embodiments of the disclosure, and cannot be understood as a limitation of the disclosure.

Although some embodiments of the general concept as disclosed herein have been illustrated and described, those skilled in the art will understand that modifications can be made without departing from the principles and spirit of the general concept of this disclosure of the disclosure as disclosed herein. The breadth and scope of the disclosure should not be limited by any of the above-mentioned exemplary embodiments, but should be limited merely by the following claims and their equivalents.

It should be noticed that the wording “comprising” does not exclude other components or steps, and the wording “a/an” or “one” does not exclude multiple or a plurality of. Furthermore, any reference numeral(s) in the claims should not be construed to be limitation of the scope of the present disclosure.

1. An electronic assembly adapted to install electronic devices, comprising:
a housing including a wall portion which circumscribes and defines a hollow chamber;
an intermediate plate provided within the chamber and fixed to the wall portion, the intermediate plate adapted to be fixedly and electrically coupled to the electronic devices;
an inlet pipe and an outlet pipe respectively formed to penetrate the wall portion and adapted to introduce a coolant into the chamber for immersing the electronic devices, and discharge the coolant from the chamber; and
a plurality of lead-wires adapted to electrically couple at least one of the electronic devices and the intermediate plate to an exterior of the housing.

2. The electronic assembly according to claim 1, wherein the wall portion includes:
a peripheral wall; and
a top wall and a bottom wall disposed opposite to each other and abutting against the peripheral wall respectively, at least one of the top wall and the bottom wall being removably joined to the peripheral wall, and the peripheral wall, the top wall and the bottom wall jointly defining the housing which is enclosed such that the chamber is in turn surrounded and enclosed therein.

3. The electronic assembly according to claim 2, wherein the chamber is in fluid communication with the exterior of the housing only via the inlet pipe and the outlet pipe, with an electrical connection between the chamber and the exterior of the housing comprising only an electrical connection between the electronic devices and the exterior of the housing via the plurality of lead-wires.

4. The electronic assembly according to claim 3, wherein the inlet pipe and the outlet pipe are distributed to extend through the peripheral wall, and the plurality of lead-wires extend through a perforated surface of at least one of the top wall and the bottom wall.

5. The electronic assembly according to claim 4, further comprising: a gasket provided between the plurality of lead-wires and the wall portion, and adapted to form a waterproof seal between the plurality of lead-wires and the wall portion.

6. The electronic assembly according to claim 5, wherein the gasket is sleeved on outer peripheries of respective lead-wires of the plurality of lead-wires, and is pressed against the perforated surface of a respective one of the top wall and the bottom wall through which the plurality of lead-wires extend, and sealing around holes formed in the perforated surface for passing the plurality of lead-wires therethrough.

7. The electronic assembly according to claim 5, wherein the gasket is a sealing liner made of a non-conductive, elastic material.

8. The electronic assembly according to claim 4, wherein the inlet pipe, the outlet pipe, and the peripheral wall are integrally formed.

9. The electronic assembly according to claim 4, wherein:
the inlet pipe and the outlet pipe are inserted in respective holes for the pipes formed through the peripheral wall; and
the electronic assembly further comprises a sealing ring provided and sleeved on outer peripheries of the inlet pipe and the outlet pipe and sealing between inner surfaces of the respective holes for the pipes on the peripheral wall and both the inlet pipe and the outlet pipe.

10. The electronic assembly according to claim 1, wherein the intermediate plate is a silicon substrate or a printed circuit board (PCB).

11. The electronic assembly (according to claim 1, wherein the coolant is water or a conductive coolant.

12. The electronic assembly according to claim 4, wherein each of the plurality of lead-wires is one of a pin, an electrical connection terminal, or a wire.

13. The electronic assembly according to claim 1, wherein the plurality of lead-wires comprise:
a plurality of power supply lead-wires electrically coupled to the intermediate plate and adapted to supply power to at least one of the electronic devices and the intermediate plate; and
a plurality of signal lead-wires, including:
a plurality of input signal lead-wires adapted to input data to at least one of the electronic devices and the intermediate plate; and
a plurality of output signal lead-wires adapted to output data from at least one of the electronic devices and the intermediate plate.

14. The electronic assembly according to claim 13, wherein:
the electronic devices include a plurality of electronic circuit units mounted to an upper surface of the intermediate plate) facing towards the top wall in a sealed package form; and
the electronic assembly further includes a plurality of voltage regulator modules (VRM) mounted on a lower surface of the intermediate plate opposite to the upper surface, with each voltage regulator module arranged to be electrically connected to a power source outside of the housing via a respective power supply lead-wire of the plurality of power supply lead-wires and to a respective electronic circuit unit of the plurality of electronic circuit units via the intermediate plate.

15. The electronic assembly according to claim 14, wherein:
the plurality of input signal lead-wires are arranged to extend from the lower surface of the intermediate plate through the bottom wall and electrically connected to the electronic devices via the intermediate plate; and
the plurality of output signal lead-wires extend from the upper surface of the intermediate plate through the top wall and are electrically connected from the electronic devices to the exterior of the housing via the intermediate plate.

16. The electronic assembly according to claim 1, further comprising a heat dissipator provided in proximity to respective package surfaces of the electronic devices or to the intermediate plate.

17. The electronic assembly according to claim 16, wherein the heat dissipator is made of metal or alloy material.

18. The electronic assembly according to claim 16, wherein the heat dissipator comprises a plurality of heat dissipating fins.

19. The electronic assembly according to claim 1, further comprising a plurality of flow guides, extending from the wall portion towards the intermediate plate and cooperatively arranged to constrain dimensions of a flow path of the coolant flowing towards the electronic devices.

20. A liquid-cooled electronic system, comprising:
a plurality of electronic devices; and
an electronic assembly adapted to install the electronic devices, comprising:
a housing including a wall portion which circumscribes and defines a hollow chamber;
an intermediate plate provided within the chamber and fixed to the wall portion, the electronic devices fixed and electrically coupled to the intermediate plate;
an inlet pipe and an outlet pipe respectively formed to penetrate the wall portion and adapted to introduce a coolant into the chamber and discharge the coolant from the chamber; and
a plurality of lead-wires through which at least one of the electronic devices and the intermediate plate is electrically coupled to an exterior of the housing, wherein each electronic device is in a sealed package form and immersed in the coolant.
